(19) United States
(12) Patent Application Publication
(10) Pub. No.: US 2017/0077320 A1
(43) Pub. Date: Mar. 16, 2017

(54) ANTI-CORROSION PROTECTION OF PHOTOVOLTAIC STRUCTURES

(71) Applicant: SolarCity Corporation, San Mateo, CA (US)

(72) Inventors: Zhi-Wen Sun, Sunnyvale, CA (US); Jianming Fu, Palo Alto, CA (US)

(73) Assignee: SolarCity Corporation, San Mateo, CA (US)

(21) Appl. No.: 15/261,507

(22) Filed: Sep. 9, 2016

Related U.S. Application Data
(60) Provisional application No. 62/217,670, filed on Sep. 11, 2015.

(51) Int. Cl. H01L 31/0216; H01L 31/18; H01L 31/0224

(52) U.S. Cl. CPC H01L 31/02167; H01L 31/022433; H01L 31/022466; H01L 31/1884; H01L 31/1868

(57) ABSTRACT

One embodiment can provide a photovoltaic structure. The photovoltaic structure can include a multilayer structure, which can include a base layer, a surface-field layer positioned on a first side of the base layer, and an emitter layer positioned on a second side of the base layer. The photovoltaic structure can further include a first metallic grid positioned on a first surface of the multilayer structure and a first organic coating covering at least sidewalls of the first metallic grid.

### CROSS-REFERENCE TO OTHER APPLICATIONS

This claims the benefit of U.S. Provisional Patent Application No. 62/217,670, Attorney Docket Number P181-1PUS, entitled “ORGANIC COATING OF CU ELECTRODES ON SILICON PHOTOVOLTAIC STRUCTURES,” filed Sep. 11, 2015, the disclosure of which is incorporated herein by reference in its entirety for all purposes.

### FIELD OF THE INVENTION

This generally relates to the fabrication of photovoltaic structures. More specifically, this is related to the fabrication of the electrical contact for photovoltaic structures.

### DEFINITIONS

“Solar cell” or “cell” is a photovoltaic structure capable of converting light into electricity. A cell may have any size and any shape, and may be created from a variety of materials. For example, a solar cell may be a photovoltaic structure fabricated on a silicon wafer or one or more thin films on a substrate material (e.g., glass, plastic, or any other material capable of supporting the photovoltaic structure), or a combination thereof.

A “solar cell strip,” “photovoltaic strip,” or “strip” is a portion or segment of a photovoltaic structure, such as a solar cell. A photovoltaic structure may be divided into a number of strips. A strip may have any shape and any size. The width and length of a strip may be the same or different from each other. Strips may be formed by further dividing a previously divided strip.

A “cascade” is a physical arrangement of solar cells or strips that are electrically coupled via electrodes on or near their edges. There are many ways to physically connect adjacent photovoltaic structures. One way is to physically overlap them at or near the edges (e.g., one edge on the positive side and another edge on the negative side) of adjacent structures. This overlapping process is sometimes referred to as “shingling.” Two or more cascading photovoltaic structures or strips can be referred to as a “cascaded string,” or more simply as a string.

“Finger lines,” “finger electrodes,” and “fingers” refer to elongated, electrically conductive (e.g., metallic) electrodes of a photovoltaic structure for collecting carriers.

A “busbar,” “bus line,” or “bus electrode” refers to an elongated, electrically conductive (e.g., metallic) electrode of a photovoltaic structure for aggregating current collected by two or more finger lines. A busbar is usually wider than a finger line, and can be deposited or otherwise positioned anywhere on or within the photovoltaic structure. A single photovoltaic structure may have one or more busbars.

A “photovoltaic structure” can refer to a solar cell, a segment, or solar cell strip. A photovoltaic structure is not limited to a device fabricated by a particular method. For example, a photovoltaic structure can be a crystalline silicon-based solar cell, a thin film solar cell, an amorphous silicon-based solar cell, a polycrystalline silicon-based solar cell, or a strip thereof.

### BACKGROUND

Advances in photovoltaic technology, which is used to make solar panels, have helped solar energy gain mass appeal among those wishing to reduce their carbon footprint and decrease their monthly energy costs. Solar cells that include electrodes made of electroplated Cu have been shown to improve the efficiency of the solar cells. However, Cu grids can be prone to oxidation and corrosion. Protecting the surface of the Cu grid lines using a corrosion-resistant material can be important in maintaining the efficiency of the solar cells during their service life.

In conventional fabrication facilities, the surface of the Cu grids can be coated with a layer of Sn using an immersion technique. However, the chemical solution used in the immersion Sn process can include thiourea or its derivatives, which can be hazardous to the environment. Carefully designed waste treatment is often needed for proper disposal of the thiourea-containing solution and, thus, can significantly increase the solar cell manufacturing cost.

### SUMMARY

One embodiment can provide a photovoltaic structure. The photovoltaic structure can include a multilayer structure, which can include a base layer, a surface-field layer positioned on a first side of the base layer, and an emitter layer positioned on a second side of the base layer. The photovoltaic structure can further include a first metallic grid positioned on a first surface of the multilayer structure and a first organic coating covering at least sidewalls of the first metallic grid.

In a variation of this embodiment, the first organic coating can include one or more of: imidazole, derivatives of imidazole, and benzotriazole.

In a variation of this embodiment, the multilayer structure can further include a transparent conductive oxide layer positioned between the first metallic grid and the base layer.

In a further variation, the first metallic grid can include a metallic seed layer formed on the transparent conductive oxide layer using a physical-vapor-deposition technique and a metallic bulk layer formed on the metallic seed layer using a plating technique.

In a further variation, the metallic seed and bulk layers can include Cu.

In a further variation, the first organic coating can cover a top surface and sidewalls of the metallic bulk layer and sidewalls of the metallic seed layer.

In a further variation, the first metallic grid can include a corrosion-resistant protection layer on a top surface of the metallic bulk layer.

In a further variation, the corrosion-resistant protection layer can include: Sn, Ag, or a combination thereof.

In a variation of this embodiment, the photovoltaic structure can include a second metallic grid positioned on a second surface of the multilayer structure and a second organic coating covering at least sidewalls of the second metallic grid.

In a variation of this embodiment, the multilayer structure can further include a passivation layer positioned on both surfaces of the base layer.

### BRIEF DESCRIPTION OF THE FIGURES

FIG. 1 shows an exemplary photovoltaic structure, according to one embodiment.

FIG. 2 shows an exemplary process of fabricating a photovoltaic structure, according to one embodiment.

FIG. 3 shows an exemplary fabrication process of a photovoltaic structure, according to one embodiment.

FIG. 4A shows an exemplary grid pattern on the front surface of a photovoltaic structure.

FIG. 4B shows an exemplary grid pattern on the back surface of a photovoltaic structure.

FIG. 5A shows a string of cascaded strips.

FIG. 5B shows a side view of the string of cascaded strips.

FIG. 6A shows the front surface of a photovoltaic structure after partial removal of the ORGANIC coating, according to one embodiment.

FIG. 6B shows the cross-sectional view of the photovoltaic structure, according to one embodiment.

FIG. 6C shows the conductive paste bonding directly to the busbar surface via openings of the organic coating, according to one embodiment.

FIG. 7 shows an exemplary system for depositing the organic-coating-dissolving solution and the conductive paste, according to one embodiment.

FIG. 8 shows the cross-sectional view of two overlapping busbars, according to one embodiment.

FIG. 9 shows the front surface of a photovoltaic structure after partial removal of the organic coating, according to one embodiment.

FIG. 10 shows an exemplary process for fabricating a solar string, according to one embodiment.

FIG. 11 shows an exemplary process for fabricating a solar string, according to one embodiment.

FIGS. 12A and 12B show the top and bottom surfaces of a string, respectively, according to one embodiment.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

### Overview

Embodiments of the present invention can provide a low-cost and environmentally friendly solution for coating metallic contacts of photovoltaic structures. In order to reduce corrosion and oxidation of the metallic contacts, an organic coating can be applied on the surface of the metallic contacts. In some embodiments, subsequent to the formation of electroplated metallic grids, the photovoltaic structure can be immersed in an aqueous solution of an organic compound, such as imidazole or its derivatives, resulting in an organic coating covering both the top surface and sidewalls of the metallic grids. To enable cascading of adjacent strips, the organic coating can also be selectively removed on certain parts of the metallic grids.

Photovoltaic Structures with Electroplated Metallic Grids

Electroplated metallic electrode grids (e.g., electroplated Cu grids) have been shown to exhibit lower resistance than conventional aluminum or screen-printed-silver-paste electrodes. Such low electrical resistance can be essential in achieving high-efficiency photovoltaic structures. In addition, electroplated copper electrodes can also tolerate microcracks better, which may occur during a subsequent cleaving process. Such microcracks might impair silver-paste-electrode cells. Plated-copper electrode, in contrast, can preserve the conductivity across the cell surface even if there are microcracks. The copper electrode's higher tolerance for microcracks allows the use of thinner silicon wafers, which can reduce the overall fabrication cost. More details on using copper plating to form low-resistance electrodes on a photovoltaic structure are provided in U.S. patent application Ser. No. 13/220,532, Attorney Docket No. P59-1NUS, entitled “SOLAR CELL WITH ELECTROPLATED GRID,” filed on Aug. 29, 2011, the disclosure of which is incorporated herein by reference in its entirety.

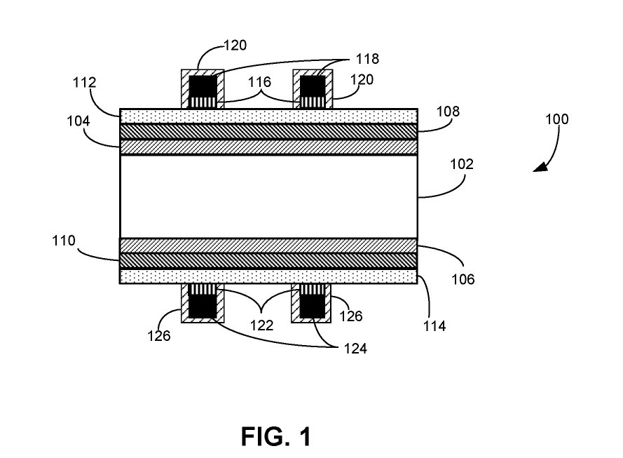

FIG. 1 shows an exemplary photovoltaic structure, according to an embodiment of the present invention. In FIG. 1, photovoltaic structure 100 can include base layer 102, front and back passivation layers 104 and 106, surface-field layer 108, emitter layer 110, front and back TCO layers 112 and 114, a front electrode grid that can include Cu seed layer 116, electroplated bulk Cu layer 118, and metallic protection layer 120, and a back electrode grid that can include Cu seed layer 122, electroplated bulk Cu layer 124, and metallic protection layer 126.

Base layer 102 can include various materials, such as undoped or lightly doped monocrystalline silicon and undoped or lightly doped microcrystalline silicon. Passivation layers 104 and 106 can include various dielectric materials, such as silicon oxide (SiOₓ) hydrogenated SiOₓ, silicon nitride (SiNₓ), hydrogenated SiNₓ, aluminum oxide (AlOₓ), silicon oxynitride (SiON), hydrogenated SiON, and any combination thereof. In addition to dielectric material, the passivation layers may also include intrinsic (e.g., undoped) silicon in various forms, such as single crystalline Si, polycrystalline Si, amorphous Si, and any combination thereof. The passivation layers can be formed using a wet process, such as wet or steam oxidation, or a chemical-vapor-deposition (CVD) process. Emitter layer 110 can include heavily doped wide bandgap material, such as amorphous Si (a-Si) or hydrogenated a-Si (a-Si:H). If base layer 102 is lightly doped, emitter layer 110 can have a conductive doping type opposite to that of base layer 102. Surface-field layer 108 can also include heavily doped wide bandgap material, such as a-Si or a-Si:H. The conductive doping type of surface-field layer 108 can be opposite to that of emitter layer 110. In some embodiments, emitter layer 110 and/or surface-field layer 108 can have a graded doping profile, with a lower doping concentration near the base/emitter or base/surface-field layer interface. The formation of emitter layer 110 and/or surface-field layer 108 can involve a CVD process, such as a plasma-enhanced chemical-vapor-deposition (PECVD) process. In the example shown in FIG. 1, emitter layer 110 is positioned on the back side of the photovoltaic structure, facing away from the incident light. In practice, the emitter can also be placed on the front side of the photovoltaic structure, facing the incident light.

Front and back TCO layers 112 and 114 can be formed using materials such as indium-tin-oxide (no), aluminum-doped zinc-oxide (ZnO:Al), gallium-doped zinc-oxide (ZnO:Ga), tungsten-doped indium oxide (IWO), Zn-in-Sn—O (ZITO), Ti-doped indium oxide, Ta-doped indium oxide, and their combinations. The TCO layers can be formed using a low-temperature PVD process. For example, the TCO layers can be formed by sputtering without intentional heating of the substrate. The TCO layers can be subsequently annealed to improve their electro-optical properties (e.g., high transparency over a wide wavelength range and low electrical resistivity).

As discussed in the aforementioned U.S. patent application Ser. No. 13/220,532, a thin metallic seed layer (e.g., Cu seed layer 116) can be deposited to improve the adhesion between the electroplated Cu grid and the underlying TCO layer using a PVD technique (e.g., sputtering or evaporation), on top of the TCO layer, because high-energy atoms sputtered from the target can adhere well to the TCO layer. This metallic seed layer can then enhance the adhesion between the TCO layer and the subsequently plated Cu grid. The thickness of the metallic seed layer can be between 20 and 500 nm.

The main body of the electrode grid (e.g., bulk Cu layers 118 and 124) can be formed using an electroplating process. As discussed previously, electroplated Cu grids can provide lower resistance and be more tolerable of microcracks. However, Cu grids can be subject to oxidation and corrosion if exposed to air. To protect the Cu grids against negative environmental factors during the service life of the photovoltaic structure, a metallic protection layer can be formed to cover the sidewalls and top surface of the Cu grids, preventing exposure of the Cu grids to the environment. For example, as shown in FIG. 1, metallic protection layer 120 is covering the sidewalls of Cu layers 116 and 118 and the top surface of Cu bulk layer 118; similarly, metallic protection layer 126 is covering the sidewalls of Cu layers 122 and 124 and the top surface of Cu bulk layer 124.

Metallic protection layers 120 and 126 can include metallic materials that can resist oxidation and corrosion and provide solderability. More specifically, Sn, Ag, or Sn/Ag alloy can often be used to form the metallic protection layers. In order to cover the sidewalls of the Cu grids, an immersion plating technique (e.g., immersion tin) can be used to form the metallic protection layers. For example, metallic protection layers 120 and 126 can include a Sn layer that is 0.3-1.0 um thick, and the Sn layer can be formed by immersing the photovoltaic structure in a solution that includes Sn ions, such that a displacement reaction can occur between the Sn ions and the Cu grids.

Because the redox potential of Cu is higher than Sn, to enable the displacement reaction, a complexing agent, such as thiourea (SC(NH₂)₂) or its derivatives, is needed to reduce the redox potential of the Cu. However, thiourea is a hazardous material and often requires carefully designed waste treatment for safe disposal. Treating thiourea waste can be expensive, thus significantly increasing the fabrication cost of the photovoltaic structures. To reduce fabrication cost and mitigate the negative effect on the environment, in some embodiments, an environmentally friendly organic compound can be used to coat the metallic grids. Such an organic coating can isolate the Cu grid lines, including the finger lines and busbars, from the environment, reducing Cu oxidation and corrosion. In some embodiments, the organic compound solution can include organic compound used in the organic solderability preservative (OSP) technology, such as imidazole or its derivatives (e.g., polybenzimidazole), and benzotriazole. The organic compound used for coating the metallic grids typically is water-based and environmentally friendly.

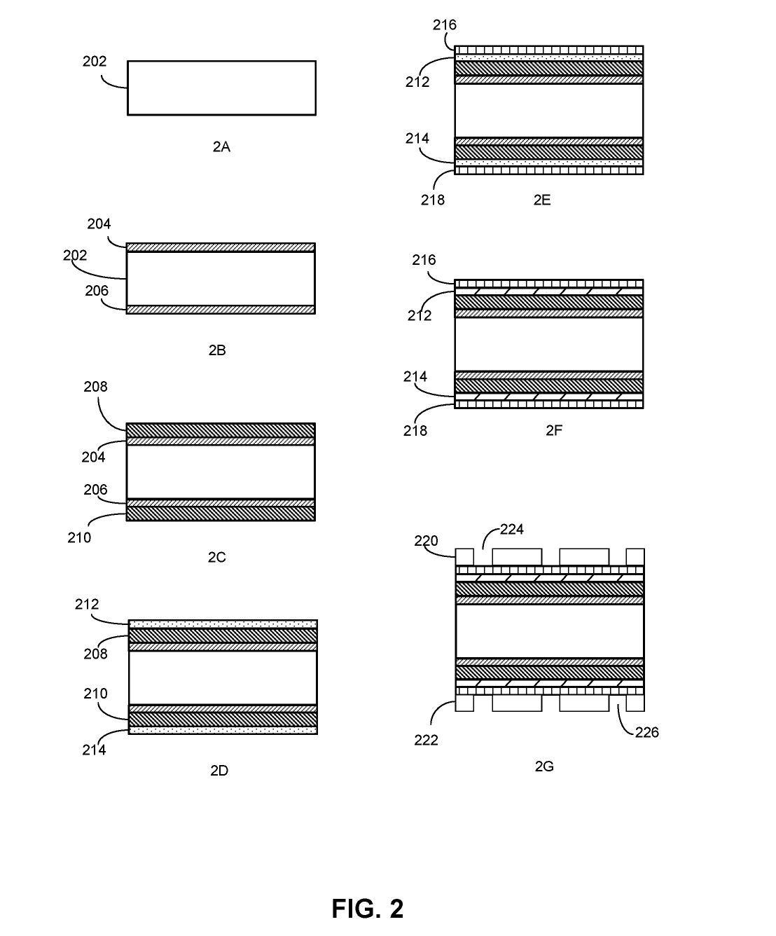

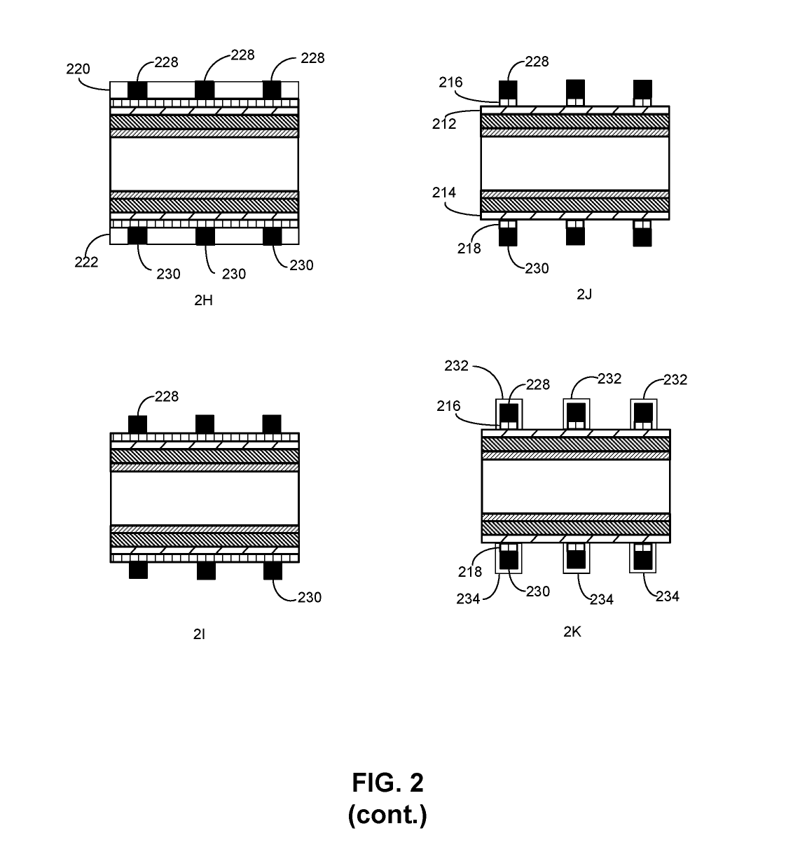

FIG. 2 shows an exemplary process of fabricating a photovoltaic structure, according to one embodiment. In operation 2A, substrate 202 can be prepared. Substrate 202 can include a crystalline-Si (c-Si) wafer (e.g., a monocrystalline or polycrystalline silicon wafer). In some embodiments, preparing c-Si substrate 202 can include standard saw-damage etching (which removes the damaged outer layer of Si substrate 202) and surface texturing. The c-Si substrate 202 can be lightly doped with either n-type or p-type dopants. In one embodiment, c-Si substrate 202 can be lightly doped with n-type dopants (e.g., phosphorus). In addition to c-Si, other materials (such as metallurgical-Si) can also be used to form substrate 202.

In operation 2B, front and back passivation layers 204 and 206 can be formed on the front and back surfaces, respectively, of substrate 202. The passivation layers can also function as quantum-tunneling barrier (QTB) layers. In some embodiments, forming passivation layers 204 and 206 can involve a wet oxidation process or a CVD process. The thickness of passivation layers 204 and 206 can be between 1 and 50 angstroms.

In operation 2C, heavily doped surface-field layer 208 and emitter layer 210 can be formed on passivation layers 204 and 206, respectively, using one or more CVD processes. In some embodiments, both surface-field layer 208 and emitter layer 210 can include hydrogenated a-Si with a graded-doping profile. For n-type doped substrate 202, surface-field layer 208 can be doped with n-type dopants (e.g., phosphorus), and emitter layer 210 can be doped with p-type dopants (e.g., boron). The thickness of surface-field layer 208 and/or emitter layer 210 can be between 2 and 50 nm.

In operation 2D, TCO layers 212 and 214 can be formed on surface-field layer 208 and emitter layer 210, respectively. Forming TCO layers 212 and 214 can involve a PVD process, such as sputtering. In some embodiments, to prevent damage to the surface of surface-field layer 208 and emitter layer 210, TCO layers 212 and 214 can be formed using a low-temperature sputtering process, which can be performed without intentional heating of the substrate or with active cooling of the substrate. More specifically, during sputtering, the temperature of the substrate is maintained below 130° C., preferably below 80° C. In some embodiments, H₂ and water vapor can also be injected into the PVD chamber to improve the film quality of TCO layers 212 and 214.

In some embodiments, TCO layers 212 and 214 can include indium oxide (In₂O₃) doped with Ti and Ta, which can provide superior electro-optical properties after annealing. The combined doping of Ti and Ta can be less than 2% by weight. Other types of TCO materials can also be possible, including but not limited to: ITO with low (e.g., less than 2% by weight) SnO₂ doping, tungsten-doped In₂O₃ (IWO), and cerium-doped indium oxide (ICeO).

In operation 2E, metallic seed layers 216 and 218 can be formed on TCO layers 212 and 214, respectively. Forming the metallic seed layers can also involve a PVD process. In some embodiments, metallic seed layers 216 and 218 can be formed using the same PVD tool that forms TCO layers 212 and 214 without disrupting the vacuum, meaning that the photovoltaic structures remain in the same vacuum environment during the deposition of all these layers. This can significantly reduce the processing time, because there is no need to pump down the PVD chamber or chambers between processes.

In operation 2F, the photovoltaic structures can be sent to an annealing oven for annealing of the TCO layers and the metallic seed layers. The annealing temperature can be set at a temperature between 200 and 230° C. and the annealing dwell time can be between 20 and 40 minutes. After the thermal annealing process, TCO layers 212 and 214 can transition from an amorphous state to a multicrystalline state with improved electro-optical properties.

In operation 2G, dry-film resist layers 220 and 222 can be laminated and patterned on metallic seed layers 216 and 218, respectively. The patterned dry-film resist layers can define the locations of the grid lines. Standard photoresist patterning processes, including exposure and development, can be used to pattern dry-film resist layers 220 and 222. Windows (e.g., windows 224 and 226) within the photoresist layers correspond to locations of the grid lines.

In operation 2H, metallic material can be deposited into windows within the photoresist layers to form metallic bulk layers 228 and 230. In some embodiments, an electroplating process can be used to deposit metallic material (e.g., Cu). More specifically, the photovoltaic structure can be submerged in an electrolyte bath containing metallic ions (e.g., Cu ions). Because the photoresist is electrically insulated, the metallic ions can only be deposited into the windows, which expose the electrically conductive metallic seed layers, within dry-film resist layers 220 and 222. The thickness of metallic bulk layers 228 and 230 can be between 10 and 200 μm.

In operation 2I, dry-film resist layers 220 and 222 can be stripped off. In operation 2J, metallic seed layers 216 and 218 can be partially etched, using bulk layers 228 and 230 as masks, to expose underlying TCO layers 212 and 214, respectively. Metallic seed layer 216 and bulk layer 228 together form the front side metallic grid, and metallic seed layer 218 and bulk layer 230 together form the back side metallic grid.

In operation 2K, the photovoltaic structure can be immersed in an aqueous solution of an organic compound (e.g., imidazole or its derivatives), resulting in organic coatings 232 and 234 being deposited over the top surface and sidewalls of the front and back metallic grids. The organic solution can be designed such that the organic compound reacts only with Cu, forming a protective coating on the Cu surface without coating the TCO layers. Organic coating 232 can cover the exposed surfaces, including the top surface and sidewalls, of Cu bulk layers 228 and seed layer 216. Similarly, organic coating 234 can cover the top surface and sidewalls of Cu bulk layer 230 and seed layer 218.

The organic coating over the surface of the Cu grids can prevent the Cu grids from exposure to the environment and, hence, can prevent oxidation and corrosion of the Cu grids during the service life of the solar panel. Moreover, the organic coating can preserve the solderability of the Cu grids, even if the fabricated photovoltaic structures were not used right away for panel assembling, which can involve soldering of the busbars. To further improve solderability and to protect against corrosion and oxidation of the Cu grids, in some embodiments, a metallic corrosion-resistant protection layer can be deposited, using an electroplating technique, on the top surface of the Cu grids.

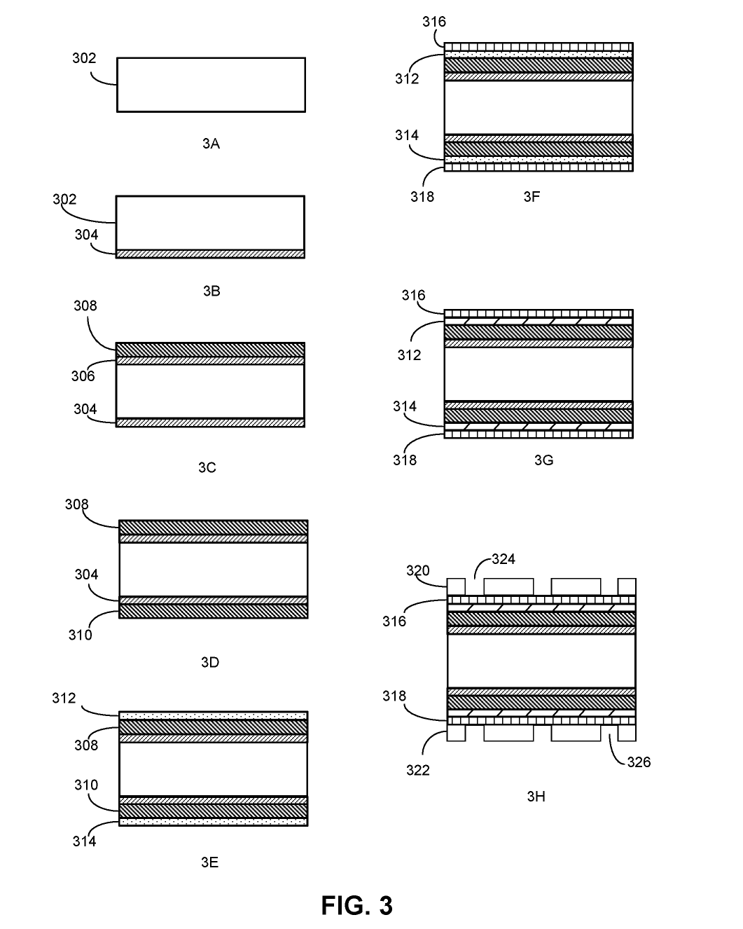

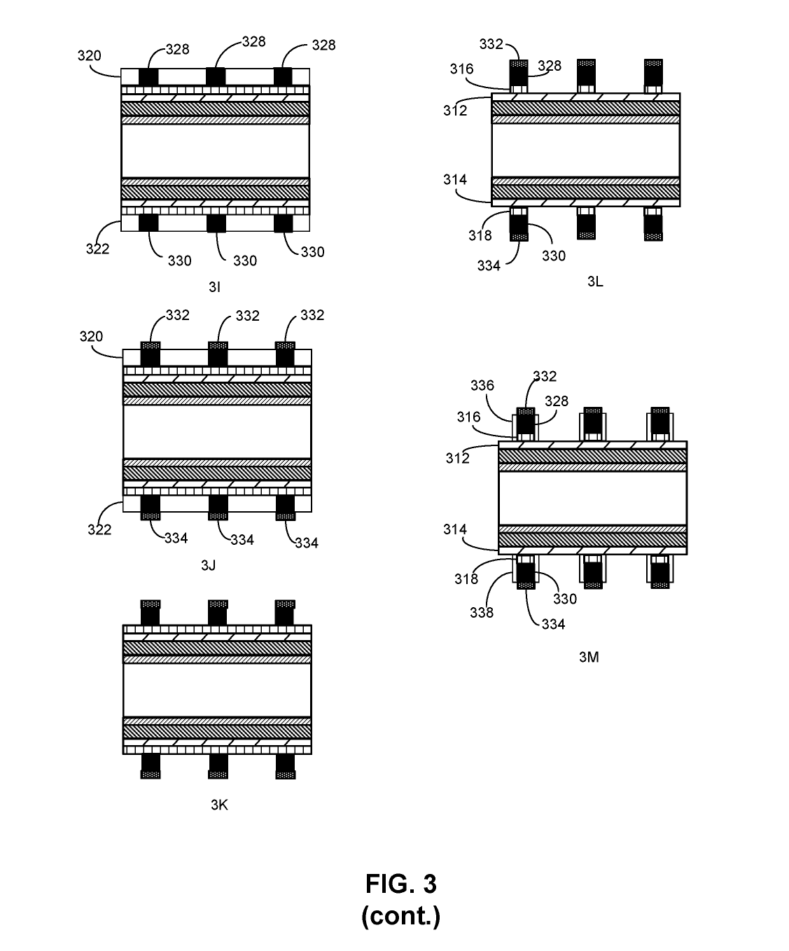

FIG. 3 shows an exemplary fabrication process of a photovoltaic structure, according to one embodiment. In operation 3A, substrate 302 can be prepared using a process similar to the one used in operation 2A. In some embodiments, substrate 302 can be lightly doped with n-type dopants (e.g., boron). In operation 3B, passivation layer 304 can be formed on the bottom side of substrate 302. In some embodiments, passivation layer 304 can include intrinsic a-Si, and forming passivation layer 304 can include a CVD process. The thickness of a-Si passivation layer 304 can be between 1 and 50 angstroms.

In operation 3C, passivation layer 306 followed by surface-field layer 308 can be formed on the top side of substrate 302. Passivation layer 306 can include intrinsic a-Si, and surface-field layer 308 can include n-type doped a-Si. In some embodiments, passivation layer 306 and surface-field layer 308 can be formed inside the same CVD chamber without disturbing the vacuum. Surface-field layer 308 can have a graded doping profile, with a doping concentration between 1×10¹⁷/cm³ and 1×10²⁰/cm³. In operation 3D, emitter layer 310 is formed on back side passivation layer 304 using a CVD technique. In some embodiments, emitter layer 310 can include p-type doped a-Si, and can have a graded doping profile, with a doping concentration between 1×10¹⁷/cm³ and 1×10²⁰/cm³.

In operation 3E, TCO layers 312 and 314 can be formed on surface-field layer 308 and emitter layer 310, respectively. In operation 3F, metallic seed layers 316 and 318 can be formed on TCO layers 312 and 314, respectively. In operation 3G, the metallic seed layers and the TCO layers can be thermal annealed. After thermal annealing, TCO layers 312 and 314 can transition from an amorphous state to a multicrystalline state. Operations 3E-3G can be similar to operations 2D-2F shown in FIG. 2.

In operation 3H, dry-film resist layers 320 and 322 can be laminated and patterned on metallic seed layers 316 and 318, respectively. Locations of the windows (e.g., windows 324 and 326) within dry-film resist layers 320 and 322 correspond to the grid line locations. In operation 3I, metallic material (e.g., Cu) can be deposited into the windows, forming metallic bulk layers 328 and 330. Operations 3H and 3I can be similar to operations 2G and 2H, respectively, shown in FIG. 2.

In operation 3J, metallic corrosion-resistant protection layers 332 and 334 can be formed on top of metallic bulk layers 328 and 330, respectively. In some embodiments, a plating technique (e.g., electroplating or electroless plating) can be used to plate a Sn layer on Cu bulk layers 328 and 330. The plated Sn layer can protect the top surface of the Cu layers from oxidation and corrosion, and can facilitate subsequent, if any, soldering on the busbars. In addition to Sn, corrosion-resistant protection layers 332 and 334 can also include Ag or a Sn/Ag alloy.

In operation 3K, dry-film resist layers 320 and 322 are removed. In operation 3L, metallic seed layers 316 and 318 can be partially etched, using bulk layers 328 and 330 as masks, to expose underlying TCO layers 312 and 314, respectively. In some embodiments, the front side metallic grid can include Cu seed layer 316, Cu bulk layer 328, and plated Sn layer 332; and the back side metallic grid can include Cu seed layer 318, Cu bulk layer 330, and plated Sn layer 334. After Sn plating, only the sidewalls of the metallic grids can be subjected to oxidation and corrosion, and protection of these sidewalls are needed.

In operation 3M, the photovoltaic structure can be immersed in the organic solution, resulting in organic coatings 336 and 338 being deposited over side walls of the front and back metallic grids, respectively. Because the organic compound only reacts with Cu, the organic coating can only be formed on the Cu surface. More specifically, organic coating 336 can be formed on sidewalls of Cu seed layer 316 and Cu bulk layer 328, without covering surfaces of TCO layer 312 and plated Sn layer 332. Similarly, organic coating 338 can be formed on sidewalls of Cu seed layer 318 and Cu bulk layer 330, without covering surfaces of TCO layer 314 and plated Sn layer 334. Subsequently, the photovoltaic structure can be rinsed using deionized water to get rid of excessive organic solution on the TCO layers, and the photovoltaic structure is ready for the next fabrication step, e.g., cascading into a string.

### Cascading Strips Having Organic Coatings

As described in U.S. patent application Ser. No. 14/563,867, a solar panel can have multiple (e.g., three) strings, each string including cascaded strips, connected in parallel. Such a multiple-parallel-string panel configuration provides the same output voltage with a reduced internal resistance. In general, a cell can be divided into n strips, and a panel can contain n strings. Each string can have the same number of strips as the number of regular photovoltaic structures in a conventional single-string panel. Such a configuration can ensure that each string outputs approximately the same voltage as a conventional panel. The n strings can then be connected in parallel to form a panel. As a result, the panel's voltage output can be the same as that of the conventional single-string panel, while the panel's total internal resistance can be 1/n of the resistance of a string. Therefore, in general, a greater n can lead to a lower total internal resistance and, hence, more power extracted from the panel. However, a tradeoff is that as n increases, the number of connections required to interconnect the strings also increases, which increases the amount of contact resistance. Also, the greater n is, the more strips a single cell needs to be divided into, which increases the associated production cost and decreases overall reliability due to the larger number of strips used in a single panel.

Another consideration in determining n is the contact resistance between the electrode and the photovoltaic structure on which the electrode is formed. The greater this contact resistance, the greater n might need to be to effectively reduce the panel's overall internal resistance. Therefore, the type of electrode can dictate the number of strips. For example, conventional silver-paste or aluminum-based electrodes typically cannot produce ideal resistance between the electrode and underlying photovoltaic structure. As a result, such electrodes may require n to be greater than four. In some embodiments of the present invention, the electrodes, including both the busbars and finger lines, can be fabricated using a combination of physical vapor deposition (PVD) and electroplating of copper as an electrode material. The resulting copper electrode can exhibit lower resistance than an aluminum or screen-printed-silver-paste electrode. Consequently, a smaller n can be used to attain the benefit of reduced panel internal resistance. In some embodiments, n can be selected to be three, which is less than the n value generally needed for cells with silver-paste electrodes or other types of electrodes. Correspondingly, two grooves can be scribed on a single cell to allow the cell to be divided into three strips.

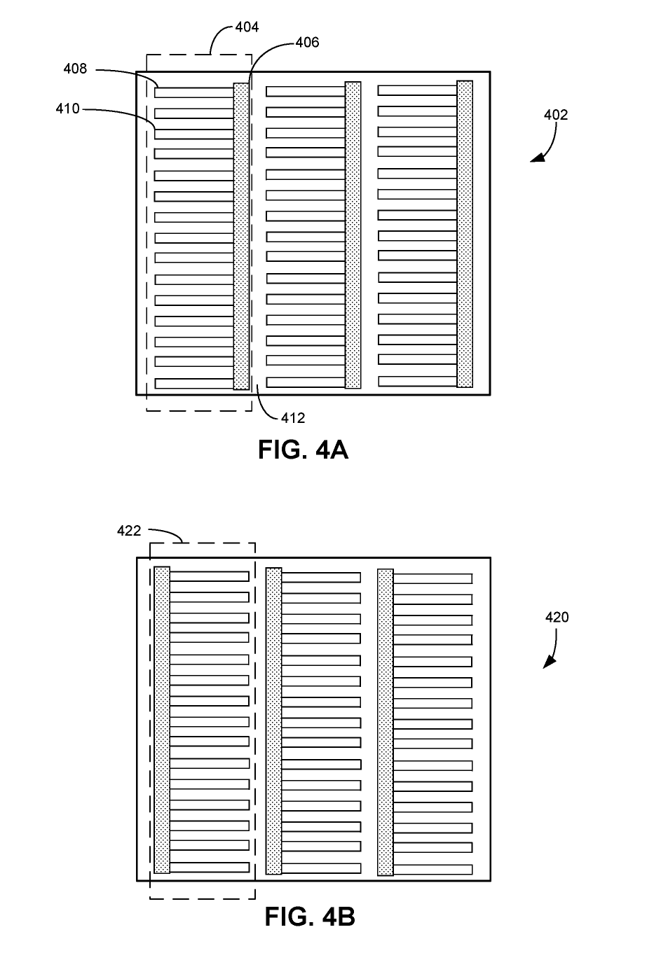

FIG. 4A shows an exemplary grid pattern on the front surface of a photovoltaic structure. In the example shown in FIG. 4A, grid 402 can include three sub-grids, such as sub-grid 404. This three sub-grid configuration can allow the photovoltaic structure to be divided into three strips. To enable cascading, each sub-grid can have an edge busbar, which can be located either at or near the edge. In the example shown in FIG. 4A, each sub-grid can include an edge busbar (“edge” here refers to the edge of a respective strip) running along the longer edge of the corresponding strip and a plurality of parallel finger lines running in a direction parallel to the shorter edge of the strip. For example, sub-grid 404 can include edge busbar 406, and a plurality of finger lines, such as finger lines 408 and 410. To facilitate the subsequent laser-assisted scribe-and-cleave process, a predefined blank space (i.e., space not covered by electrodes) can be inserted between the adjacent sub-grids. For example, blank space 412 can be defined to separate sub-grid 404 from its adjacent sub-grid. In some embodiments, the width of the blank space, such as blank space 412, can be between 0.1 mm and 5 mm, preferably between 0.5 mm and 2 mm. There is a tradeoff between a wider space that leads to a more tolerant scribing operation and a narrower space that leads to more effective current collection. In a further embodiment, the width of such a blank space can be approximately 1 mm.

FIG. 4B shows an exemplary grid pattern on the back surface of a photovoltaic structure. When showing the back surface, for illustration purposes, the photovoltaic structure is assumed to be transparent. The grid patterns on the front and back surfaces of the photovoltaic structure are viewed from the same viewing point. In the example shown in FIG. 4B, back grid 420 can include three sub-grids, such as sub-grid 422. To enable cascaded and bifacial operation, the back sub-grid may correspond to the front sub-grid. More specifically, the back edge busbar can be located at the opposite edge of the front side edge busbar. In the examples shown in FIGS. 4A and 4B, the front and back sub-grids can have similar patterns except that the front and back edge busbars are located adjacent to opposite edges of the strip. In addition, locations of the blank spaces in back conductive grid 420 can correspond to locations of the blank spaces in front conductive grid 402, such that the grid lines do not interfere with the subsequent scribe-and-cleave process. In practice, the finger line patterns on the front and back sides of the photovoltaic structure may be the same or different.

In the examples shown in FIGS. 4A and 4B, the finger line patterns can include continuous, non-broken loops. For example, as shown in FIG. 4A, finger lines 408 and 410 can both include connected loops. This type of “looped” finger line pattern can reduce the likelihood of the finger lines peeling away from the photovoltaic structure after long use. Optionally, the sections where parallel lines are joined can be wider than the rest of the finger lines to provide more durability and prevent peeling. Patterns other than the one shown in FIGS. 4A and 4B, such as un-looped straight lines or loops with different shapes, are also possible.

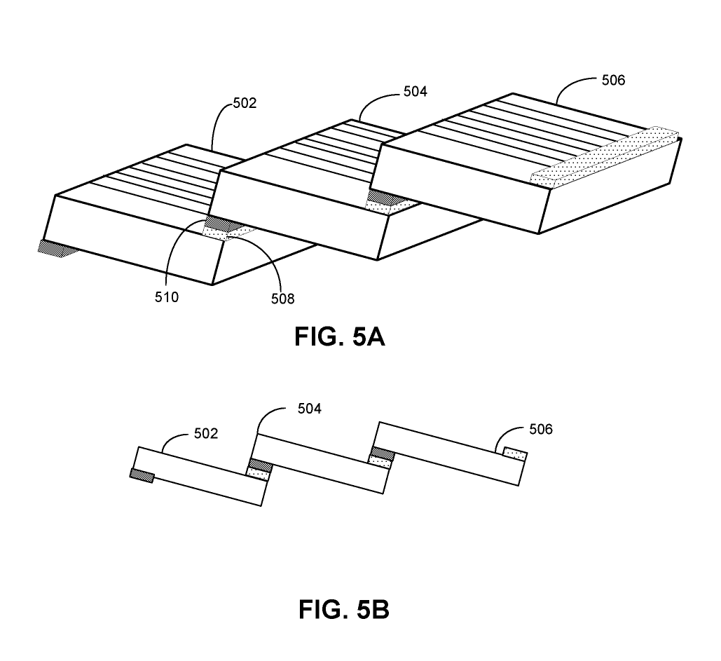

To form a cascaded string, cells or strips (e.g., as a result of a scribing-and-cleaving process applied to a regular square cell) can be cascaded with their edges overlapped. FIG. 5A shows a string of cascaded strips. In FIG. 5A, strips 502, 504, and 506 can be stacked in such a way that strip 506 can partially overlap adjacent strip 504, which can also partially overlap (on an opposite edge) strip 502. Such a string of strips can form a pattern that is similar to roof shingles. Each strip can include top and bottom edge busbars located at opposite edges of the top and bottom surfaces, respectively. Strips 502 and 504 may be coupled to each other via an edge busbar 508 located at the top surface of strip 502 and an edge busbar 510 located at the bottom surface of strip 504. To establish electrical coupling, strips 502 and 504 can be placed in such a way that bottom edge busbar 510 is placed on top of and in direct contact with top edge busbar 508.

FIG. 5B shows a side view of the string of cascaded strips. In the example shown in FIGS. 5A and 5B, the strips can be part of a 6-inch square photovoltaic structure, with each strip having a dimension of approximately 2 inches by 6 inches. To reduce shading, the overlapping between adjacent strips should be kept as small as possible. In some embodiments, the single busbars (both at the top and the bottom surfaces) can be placed at the very edge of the strip (as shown in FIGS. 5A and 5B). The same cascaded pattern can extend along an entire row of strips to form a serially connected string.

When forming a solar panel, adjacent strips may be bonded together via edge busbars. Such bonding can be important to ensure that the electrical connections are well maintained when the solar panel is put into service. One option for bonding the metallic busbars can include soldering. For example, the plated Sn on the top surface of busbars can facilitate soldering between the overlapping busbars. More specifically, heat and pressure used in the subsequent lamination process can solder together the edge busbars that are in contact, such as edge busbars 508 and 510. However, the rigid bonding between the soldered contacts may lead to cracking of the thin strips. Moreover, when in service solar panels often experience many temperature cycles, and the thermal mismatch between the metal and the semiconductor may create structural stress that can lead to fracturing.

To reduce the thermal or mechanical stress, it can be preferable to use a bonding mechanism that is sufficiently flexible and can withstand many temperature cycles. One way to do so is to bond the strips using flexible adhesive that is electrically conductive. For example, adhesive (or paste) can be applied on the surface of top edge busbar 508 of strip 502 (shown in FIG. 5A). When strip 504 is placed to partially overlap with strip 502, bottom edge busbar 510 can be bonded to top edge busbar 508 by the adhesive, which can be cured at an elevated temperature. Different types of conductive adhesive or paste can be used to bond the busbars. In one embodiment, the conductive paste can include a conductive metallic core surrounded by a resin. When the paste is applied to a busbar, the metallic core establishes an electrical connection with the busbar while the resin that surrounds the metallic core functions as an adhesive. In another embodiment, the conductive adhesive may be in the form of a resin that includes a number of suspended conductive particles, such as Ag or Cu particles. The conductive particles may be coated with a protective layer. When the paste is thermally cured, the protective layer can evaporate to enable electrical conductivity between the conductive particles suspended inside the resin.

It has been shown that the conductive paste can provide high-quality bonding between metallic surfaces (e.g., Cu surfaces). However, the conductive paste may not be able to provide sufficient bonding for busbars coated with the organic coating, because the conductive paste does not stick well to the organic coating. To solve this problem, in some embodiments, the organic coatings on the busbars can be partially removed, particularly at locations where droplets of conductive paste are deposited. By locally removing the organic coating, one can ensure that the conductive paste is in direct contact with the underlying Cu surface, thus enabling strong mechanical bonding.

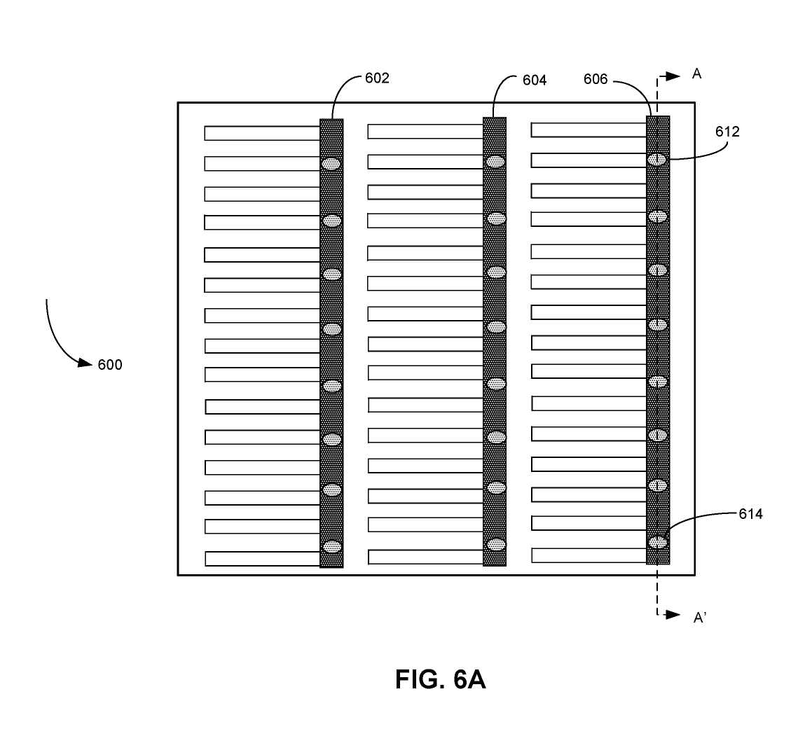

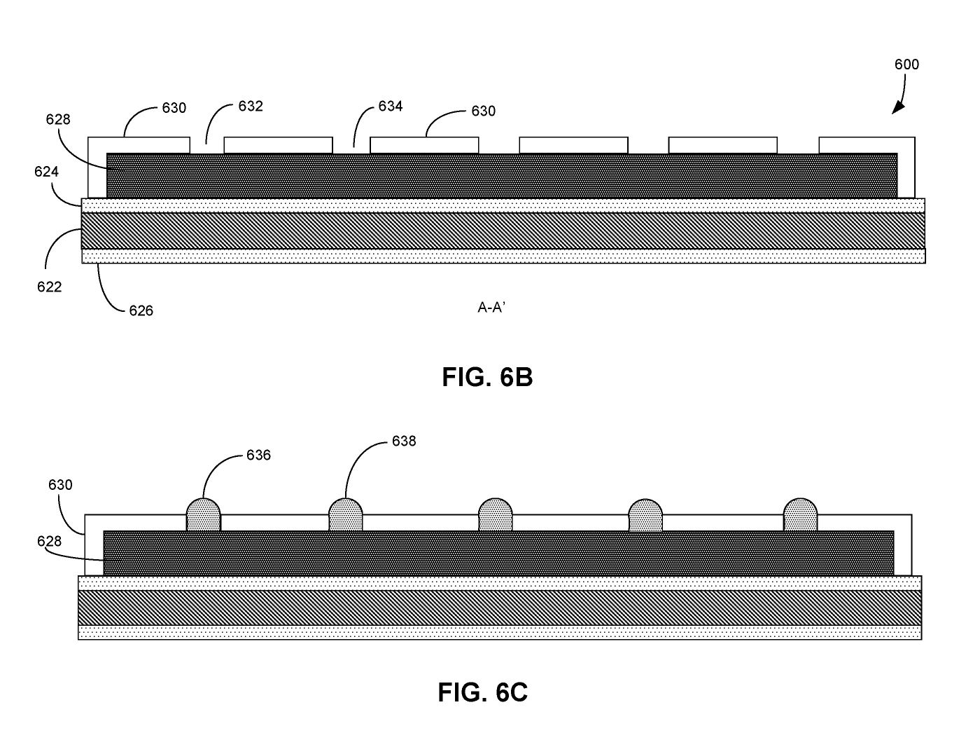

FIG. 6A shows the front surface of a photovoltaic structure after partial removal of the organic coating, according to one embodiment. Photovoltaic structure 600 can include three sub-grids; each sub-grid can include an edge busbar (e.g., edge busbars 602, 604, and 606) and a number of finger lines. The busbars and the finger lines are all coated with an organic coating, which is transparent and covers the top surface of sidewalls of the busbars and finger lines. In some embodiments, a number of openings can be created in the organic coating of each busbar. For example, the organic coating of busbar 606 can include a number of openings, e.g., openings 612 and 614.

FIG. 6B shows the cross-sectional view of the photovoltaic structure, according to one embodiment. More specifically, FIG. 6B shows the cross-sectional view of photovoltaic structure 600 along cut plane A-A′. Photovoltaic structure 600 can include photovoltaic body 622, TCO layers 624 and 626, metallic busbar 628, and organic coating 630. Photovoltaic body 622 often can include a Si base layer and an emitter layer. Photovoltaic body 622 can optionally include other layers that can enhance the energy-conversion efficiency, such as quantum-tunneling barrier (QTB) layers and a surface-field layer. The scope of the instant application cannot be limited by the specific structure of photovoltaic body 622. Metallic busbar 628 can include one or more metallic layers, such as a Cu seed layer and an electroplated Cu bulk layer. Organic coating 630 can cover the top surface and sidewalls of busbar 628, with a number of openings (e.g., openings 632 and 634) partially exposing the top surface of busbar 628. These openings allow subsequently deposited conductive paste to directly bond with the Cu surface.

FIG. 6C shows the conductive paste bonding directly to the busbar surface via openings of the organic coating, according to one embodiment. Droplets of conductive paste (e.g., droplets 636 and 638) can be deposited into the openings of organic coating 630, thus bonding directly to the top surface of metallic busbar 628.

Different techniques can be used to create openings in the organic coating. In some embodiments, mechanical probes can be used to physically remove portions of the organic coating on the busbars. For example, one or more mechanical probes can be lowered onto the surface of the busbars and gently punch through the organic coating on the surface of the busbars to locally remove portions of the organic coating. The shape of the probe heads can determine the shape of the openings. Alternatively, portions of the organic coating can be removed using a chemical solution (e.g., an acid or a solvent). The organic coating can be dissolved in acidic solutions as well as common cleaning solvents, including alcohol. In some embodiments, a dispenser can be used to deposit droplets of the organic-coating-dissolving solution at desired locations on the busbar. There droplets of the organic-coating-dissolving solution can locally dissolve the organic coating to allow subsequently deposited conductive paste to come into contact with the metallic surface of the busbars.

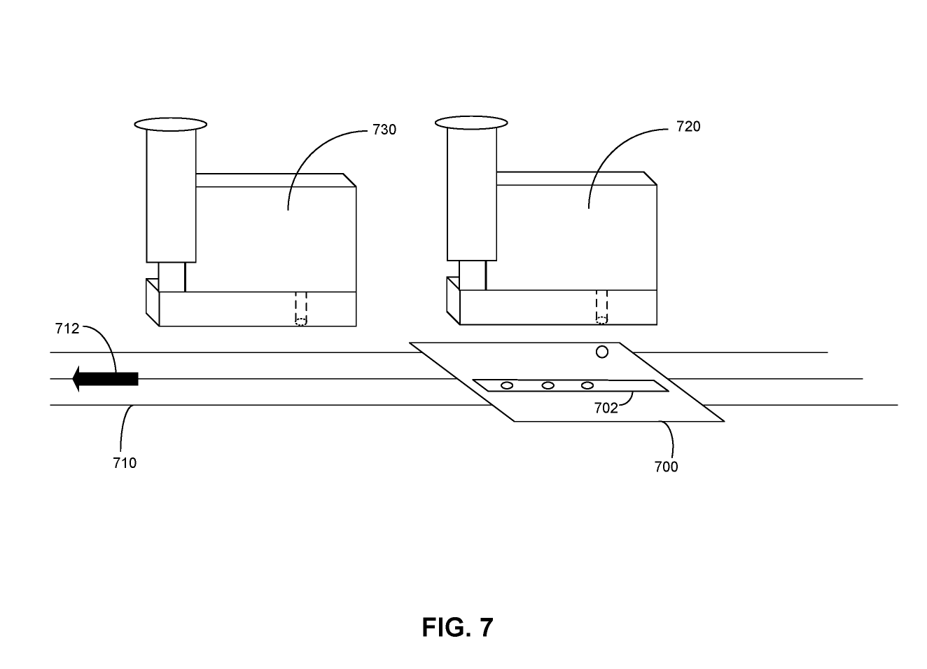

Because the conductive paste is often deposited onto the busbars using dispensers, one can configure the dispenser used for dispensing the organic-coating-dissolving solution the same way as the paste dispenser, such that droplets of the organic-coating-dissolving solution and droplets of the conductive paste can be deposited at the same locations. FIG. 7 shows an exemplary system for depositing the organic-coating-dissolving solution and the conductive paste, according to one embodiment. In FIG. 7, photovoltaic structure 700 is carried by conveyor system 710, travelling in a direction indicated by arrow 712. When photovoltaic structure 700 is underneath stationary organic-coating-dissolving solution dispenser 720, organic-coating-dissolving solution dispenser 720 can deposit droplets of an organic-coating-dissolving solution (e.g., an acid or a solvent) on busbar 702 of photovoltaic structure 700. The surface of busbar 702 is coated with an organic coating, and the droplets of the organic-coating-dissolving solution can dissolve portions of the organic coating that come into contact with these droplets.

Photovoltaic structure 700 can continue to travel along conveyor system 710 and arrive at a location underneath stationary conductive-paste dispenser 730, which can then deposit droplets of conductive paste along busbar 702. Organic-coating-dissolving solution dispenser 720 and conductive-paste dispenser 730 can be similar and can be configured in a way such that they deposit droplets at the same locations on busbar 702, meaning that the conductive paste droplets are deposited at locations where the organic coating is dissolved.

More details about the conductive-paste dispenser can be found in U.S. patent application Ser. No. 14/866,806, Attorney Docket No. P103-6NUS, entitled “METHODS AND SYSTEMS FOR PRECISION APPLICATION OF CONDUCTIVE ADHESIVE PASTE ON PHOTOVOLTAIC STRUCTURES,” filed on Sep. 25, 2015, the disclosure of which is incorporated herein by reference in its entirety.

Moreover, it is also possible to modify the composition of the conductive paste by mixing the organic-coating-dissolving solution with the conductive paste. This way, when droplets of conductive paste are deposited onto the busbars, they can dissolve the underlying organic coating to come in direct contact with the metallic surface of the busbars. After the deposition of the conductive paste, the photovoltaic structure can be divided into multiple strips, and strings can be formed by cascading multiple strips in an edge-overlapping way. Note that, if the conductive paste itself includes organic-coating-dissolving solution, it can dissolve the organic coating on both busbars, the one beneath the paste droplets and the one above.

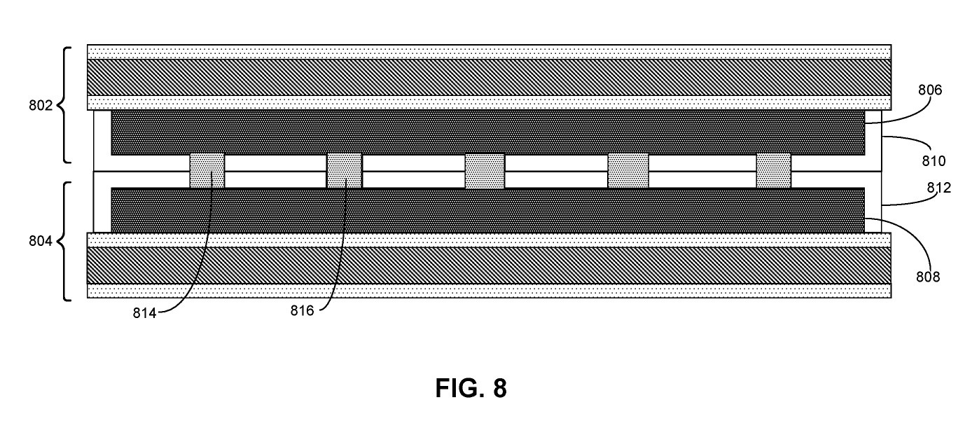

FIG. 8 shows the cross-sectional view of two overlapping busbars, according to one embodiment. Photovoltaic structures 802 and 804 are partially overlapped at the edges such that metallic busbar 806 of photovoltaic structure 802 is above metallic busbar 808 of photovoltaic structure 804, with organic coatings 810 and 812 sandwiched between busbars 806 and 808. Organic coatings 810 and 812 cover the top surface and sidewalls of busbars 806 and 808, respectively. Organic coatings 810 and 812 each can include a number of openings such that droplets of conductive paste (e.g., droplets 814 and 816) can come into contact directly with the metallic surfaces of busbars 806 and 808, thus securely bonding together photovoltaic structures 802 and 804.

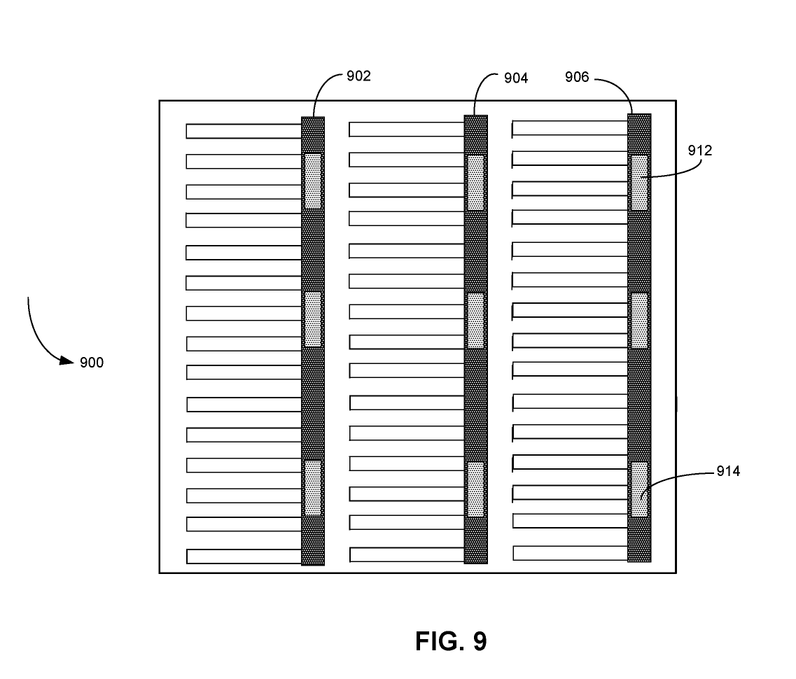

Depending on the way the conductive paste is applied, the openings in the organic coating may have different forms. FIG. 9 shows the front surface of a photovoltaic structure after partial removal of the organic coating, according to one embodiment. In the example shown in FIG. 9, rectangular shaped openings can be created in the organic coatings on busbars 902-906 of photovoltaic structure 900. For example, rectangular openings 912 and 914 can be created in the top organic coating of busbar 906. Other types of openings can also be possible, as long as the subsequently deposited conductive paste can fill the openings in the organic coating to prevent exposure of the busbar surface.

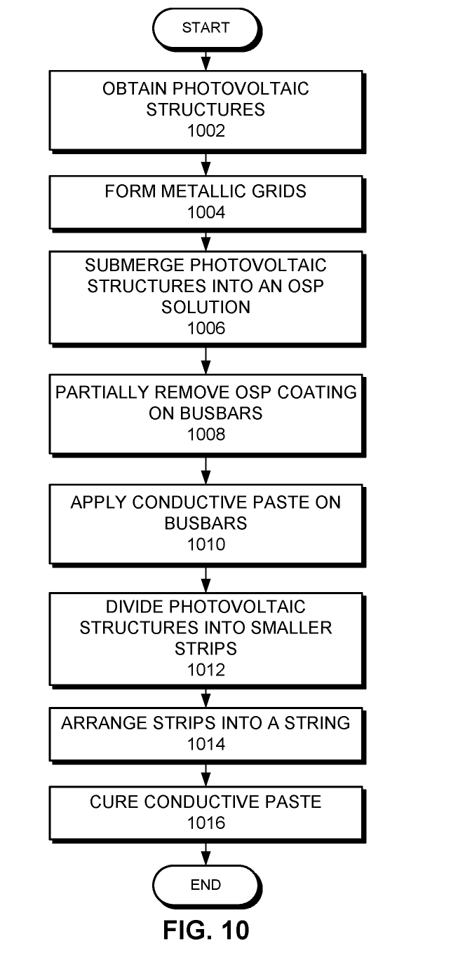

FIG. 10 shows an exemplary process for fabricating a solar string, according to one embodiment. During fabrication, a number of photovoltaic structures can be obtained (operation 1002). The photovoltaic structure can include the base, the emitter, and/or the surface-field layer. The photovoltaic structure can also optionally include a passivation layer on one or both sides of the base layer. The photovoltaic structure can include a TCO layer on one or both sides of the base layer. The TCO layer can be formed using a low temperature PVD process, and can include Ti- and/or Ta-doped In₂O₃. Metallic grids can be formed on both sides of the photovoltaic structures (operation 1004). Forming a metallic grid can involve depositing, using a PVD technique, a metallic seed layer (e.g., a Cu seed layer) on the TCO layer, and depositing, using a plating technique, a metallic bulk layer (e.g., an electroplated Cu layer) on the seed layer. In some embodiments, the metallic grid can also include a cap layer (e.g., a Sn layer), formed using a plating technique, on top of the metallic bulk layer. A thermal annealing process can also be performed to anneal the TCO layers and the metallic seed layers.

Subsequently, the photovoltaic structures are submerged into an organic solution, resulting in a layer of organic coating being formed on exposed Cu surfaces (operation 1006). If the Cu grids do not have a Sn cap layer, the organic coating will be formed on the top surface and sidewalls of the Cu grids; otherwise, the organic coating will be formed only on the sidewalls of the Cu grids. The organic solution can include an aqueous solution of certain organic compounds. Examples of the organic compounds can include imidazole, polybenzimidazole, benzotriazole, etc.

After the organic coating, the photovoltaic structures can be rinsed and dried, and sent to an automated tool for the formation of a string or panel. More specifically, portions of organic coating on the busbars of the photovoltaic structures can be removed (operation 1008). Various organic-coating-removal techniques can be used. In some embodiments, the organic coating can be partially removed mechanically, which can involve using mechanical probes to puncture holes in the organic coating at desired locations. Alternatively, the organic coating can be removed chemically, which can involve applying organic-coating-dissolving solution at desired locations. Subsequently, conductive paste can be applied onto the busbars at locations where the organic coating is removed (operation 1010). In some embodiments, the conductive paste can be combined with organic-coating-dissolving solution, and operations 1008 and 1010 can be performed as a combined step.

After the application of the conductive paste, the photovoltaic structures can be divided into smaller strips (operation 1012). Dividing the photovoltaic structures can involve scribing and cleaving operations. Multiple strips can then be arranged into an edge-overlapped fashion to form a string (operation 1014). More specifically, the edge busbar of a strip is overlapped with an opposite edge busbar of an adjacent strip. The conductive paste can be sandwiched between the overlapping busbars. The entire string can then go through a thermal treatment (e.g., being placed underneath a radiator), which cures the conductive paste, securely bonding the strips (operation 1014).

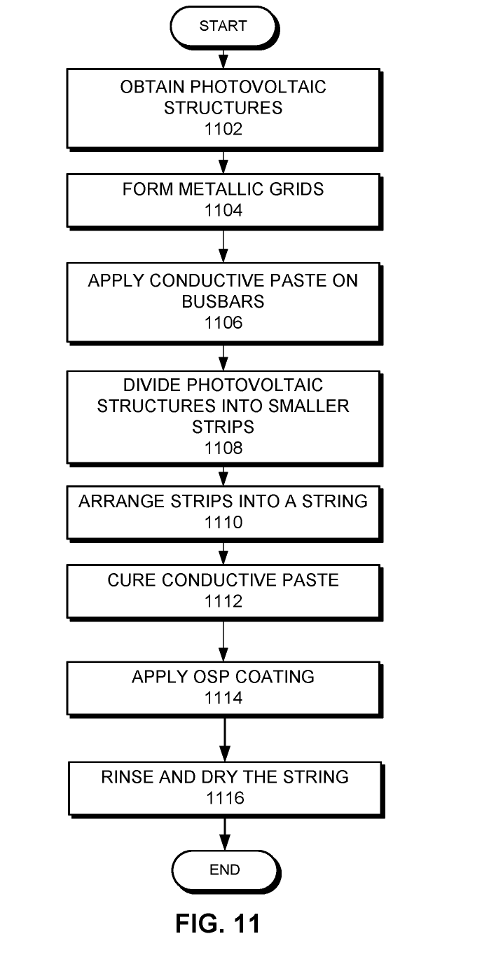

In the examples shown in FIGS. 6A-10, the organic coating is applied onto individual photovoltaic structures, and the organic coating has to be locally removed to allow conductive paste to bond with the metallic surface of the busbars. Alternatively, one can also form a string first by applying and curing the conductive paste, and then spray the surfaces of the entire string or submerge the entire string in the organic solution to coat any exposed Cu surface with an organic coating. FIG. 11 shows an exemplary process for fabricating a solar string, according to one embodiment.

During fabrication, a number of photovoltaic structures can be obtained (operation 1102), and metallic grids can be formed on both sides of the photovoltaic structures (operation 1104). Operations 1102 and 1104 can be similar to operations 1002 and 1004. After metallization, the photovoltaic structures can be sent directly to the automated tool for the formation of a string or panel. More specifically, conductive paste can be applied onto busbars (operation 1106), and the photovoltaic structures can be divided into smaller strips (operation 1108). The strips can then be arranged into a string formation (operation 1110), and the string can be heated to cure the conductive paste (operation 1112). Operations 1106-1112 can be similar to operations 1010-1016.

After the string is formed, exposed Cu surfaces (including the top surface and sidewalls of the finger lines and non-overlapping busbars) of the entire string can be coated with an organic coating (operation 1114). In some embodiments, the entire string can be immersed into an organic solution. Other coating methods, such as spraying and curtain coating can also be used. Subsequently, the string can be rinsed and dried, and is ready for panel formation (operation 1116).

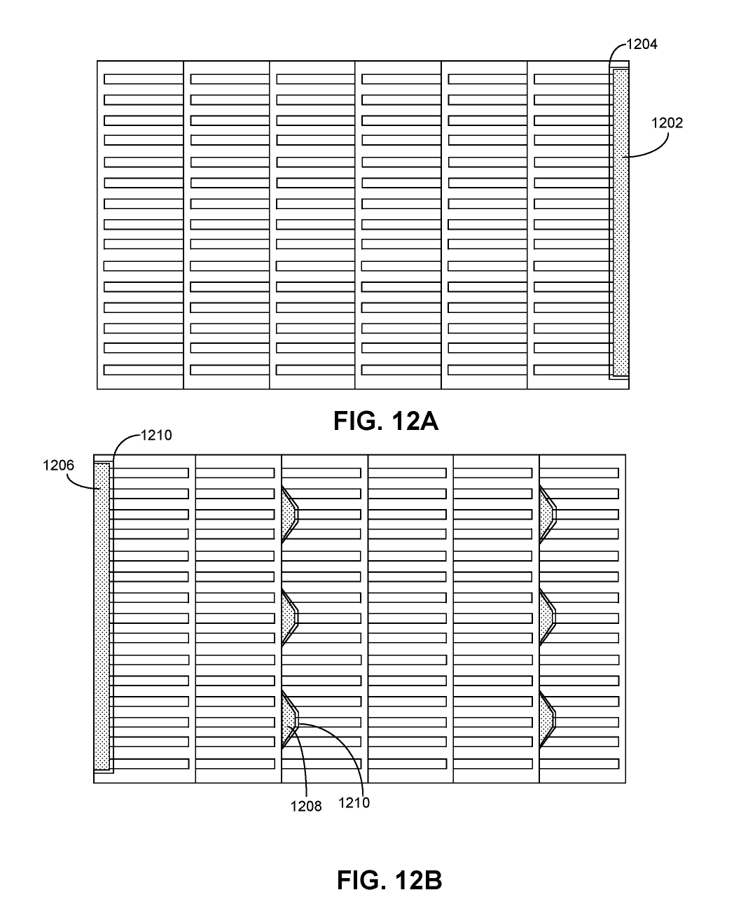

FIGS. 12A and 12B show the top and bottom surfaces of a string, respectively, according to one embodiment. In the example shown in FIGS. 12A-12B, the entire string as a whole went through the organic coating process. As a result, the exposed busbar on the top surface of the string, busbar 1202, is coated with an organic coating 1204, which covers the top surface and sidewalls of busbar 1202. In addition, the top surface and sidewalls of the finger lines are also covered with the organic coating.

Similarly, the exposed busbars on the bottom surface of the string, including busbar 1206 and contact pads (e.g., contact pad 1208) are coated with an organic coating 1210, which covers the top surface and sidewalls of the exposed busbars. The finger lines on the bottom surface are also covered with the organic coating.

The contact pads are designed to allow electrical access to the string via a conductive back sheet. More specifically, external circuitry or other strings can establish an electrically conducting path to the contact pads via conductive paste and the conductive back sheet. More details about the contact pads can be found in U.S. patent application Ser. No. 14/831,767, Attorney Docket No. P142-1NUS, entitled “PHOTOVOLTAIC ELECTRODE DESIGN WITH CONTACT PADS FOR CASCADED APPLICATION,” filed on Aug. 20, 2015, the disclosure of which is incorporated herein by reference in its entirety. To facilitate bonding between the contact pads and conductive paste, the organic coating on the contact pads may need to be partially removed.

Applying organic coatings over the metallic grids can provide a number of advantages. More specifically, compared to the conventional immersion Sn technique, the organic coating can provide a cheaper and environmentally friendly way of preventing oxidation and corrosion of the metallic grids. In addition, the organic coating operation can be compatible with other existing fabrication processes.

The foregoing descriptions of various embodiments have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention.

What is claimed is:

1. A photovoltaic structure, comprising:
a multilayer structure comprising a base layer, a surface-field layer positioned on a first side of the base layer, and an emitter layer positioned on a second side of the base layer;
a first metallic grid positioned on a first surface of the multilayer structure; and
a first organic coating covering at least sidewalls of the first metallic grid.

2. The photovoltaic structure of claim 1, wherein the first organic coating comprises one or more of: imidazole, derivatives of imidazole, and benzotriazole.

3. The photovoltaic structure of claim 1, wherein the multilayer structure further comprises a transparent conductive oxide layer positioned between the first metallic grid and the base layer.

4. The photovoltaic structure of claim 3, wherein the first metallic grid further comprises:
a metallic seed layer formed on the transparent conductive oxide layer using a physical-vapor-deposition technique; and
a metallic bulk layer formed on the metallic seed layer using a plating technique.

5. The photovoltaic structure of claim 4, wherein the metallic seed and bulk layers comprise Cu.

6. The photovoltaic structure of claim 4, wherein the first organic coating covers:
a top surface and sidewalls of the metallic bulk layer; and
sidewalls of the metallic seed layer.

7. The photovoltaic structure of claim 4, wherein the first metallic grid further comprises a corrosion-resistant protection layer on a top surface of the metallic bulk layer.

8. The photovoltaic structure of claim 7, wherein the corrosion-resistant protection layer comprises: Sn, Ag, or a combination thereof.

9. The photovoltaic structure of claim 1, further comprising:
a second metallic grid positioned on a second surface of the multilayer structure; and
a second organic coating covering at least sidewalls of the second metallic grid.

10. The photovoltaic structure of claim 1, wherein the multilayer structure further comprises a passivation layer positioned on both surfaces of the base layer.

11. A method for fabricating a photovoltaic structure, comprising:
obtaining a multilayer structure, wherein the multilayer structure comprises a base layer, a surface-field layer positioned on a first side of the base layer, and an emitter layer positioned on a second side of the base layer;
forming a first metallic grid on a first surface of the multilayer structure; and
forming a first organic coating over the first metallic grid, wherein the first organic coating is configured to cover at least sidewalls of the first metallic grid.

12. The method of claim 11, wherein forming the first organic coating comprises submerging the photovoltaic structure in a solution comprising one or more of: imidazole, derivatives of imidazole, and benzotriazole.

13. The method of claim 11, wherein obtaining the multilayer structure further comprises forming a transparent conductive oxide layer between the first metallic grid and the base layer.

14. The method of claim 13, wherein forming the first metallic grid comprises:
depositing, using a physical-vapor-deposition technique, a metallic seed layer on the transparent conductive oxide layer; and
depositing, using a plating technique, a metallic bulk layer on the metallic seed layer.

15. The method of claim 14, wherein the metallic seed and bulk layers comprise Cu.

16. The method of claim 14, wherein the first organic coating is configured to cover:
a top surface and sidewalls of the metallic bulk layer; and
sidewalls of the metallic seed layer.

17. The method of claim 14, wherein forming the first metallic grid further comprises depositing a corrosion-resistant protection layer on a top surface of the metallic bulk layer.

18. The method of claim 17, wherein depositing a corrosion-resistant cap layer comprises plating a metallic layer comprising Sn, Ag, or Sn/Ag alloy on the top surface of the metallic bulk layer.

19. The method of claim 11, further comprising:
forming a second metallic grid on a second surface of the multilayer structure; and
forming a second organic coating over the second metallic grid, wherein the second organic coating is configured to cover at least sidewalls of the second metallic grid.

20. The method of claim 11, further comprising forming a passivation layer on both surfaces of the base layer.
